(19) United States
(12) Patent Application Publication
(10) Pub. No.: US 2008/0067651 A1
(43) Pub. Date: Mar. 20, 2008

(54) METHOD AND APPARATUS FOR PREVENTION OF SOLDER CORROSION UTILIZING FORCED AIR

(75) Inventors: Gary F. Goth, Pleasant Valley, NY (US); William P. Kostenko, Poughkeepsie, NY (US); John J. Loparco, Poughkeepsie, NY (US); Prabjit Singh, Poughkeepsie, NY (US); John G. Torok, Poughkeepsie, NY (US)

Correspondence Address: CANTOR COLBURN LLP-IBM POUGHKEEPSIE, 20 Church Street, 22nd Floor, Hartford, CT, 06103, US

(73) Assignee: INTERNATIONAL BUSINESS MACHINES CORPORATION, Armonk, NY (US)

(21) Appl. No.: 11/532,396

(22) Filed: Sep. 15, 2006

(51) Int. Cl. H01L 21/00

(52) U.S. Cl. 257/678; 438/106

(57) ABSTRACT

Disclosed is a multi-chip module with solder corrosion prevention including one or more chips connected to a substrate by soldering, the substrate situated on a printed circuit board. The multi-chip module also includes a molecular sieve desiccant chamber containing a quantity of molecular sieve desiccant and a first cover to contain the one or more chips, the substrate, and the molecular sieve desiccant, the first cover having a seal to the printed circuit board. The molecular sieve desiccant chamber is connected to the first cover via a first fluid pathway and a second fluid pathway.

### FIELD OF THE INVENTION

The present invention relates in general to the field of electronics packaging. In particular, the present invention relates to electronics packaging that provides moisture and carbon dioxide adsorption for a chip module utilizing forced air.

### DESCRIPTION OF THE BACKGROUND

Electronic components, such as microprocessors and integrated circuits, are generally packaged using electronic packages (i.e., modules) that include a module substrate to which one or more electronic components are electrically connected. A single-chip module (SCM) contains a single electronic component such as a central processor unit (CPU), memory, application-specific integrated circuit (ASIC) or other integrated circuit. A multi-chip module (MCM), on the other hand, contains two or more such electronic components.

Generally, each of these electronic components takes the form of a semiconductor chip or die having an array of spaced-apart terminals or pads on its base to provide base-down mounting of the chip to the module substrate. The module substrate is typically a ceramic carrier or other conductor-carrying substrate.

Controlled collapse chip connection (C4) solder joints are typically used to electrically connect the terminals or pads on the base of the chip with corresponding terminals or pads on the module substrate. C4 solder joints are disposed on the base of the chip in an array of minute solder balls (e.g., on the order of 100 μm diameter and 200 μm pitch). The solder balls, which are typically lead (Pb)— containing solder, are reflowed to join (i.e., electrically and mechanically) the terminals or pads on the base of the chip with corresponding terminals or pads on the module substrate.

Typically, a non-conductive polymer underfill is disposed in the space between the base of the chip and the module substrate after electrical connection thereof and encapsulates the C4 solder joints. The C4 solder joints are embedded in this polymeric underfill and are thus protected from corrosion caused by moisture and carbon dioxide in the air. However, as discussed below, the use of the polymeric chip underfill prevents the assembled chip/module substrate from being reworkable.

Typically, without polymeric chip underfill, the C4 solder joints would corrode, and electrically short neighboring C4 solder joints. The presence of moisture (H₂O) and atmospheric carbon dioxide (CO₂) are the principle factors leading to corrosion of the Pb-containing C4 solder joints.

One approach has been proposed to simultaneously address the issue of C4 solderjoint corrosion as well as the desire to provide reworkability. An example of such an approach is a proposed multi-chip module assembly that utilizes a C-ring seal, which is interposed between a module substrate and a cap. The C-ring seal is utilized to reduce leakage into the module cavity, thus eliminating the need for polymeric underfill to prevent corrosion of the C4 solder joints. Unfortunately, the C-ring seal requires a larger module substrate and a larger cap compared to a module utilizing underfill resulting in the loss of precious PCB real estate (i.e., the larger footprint of module substrate and cap occupies a larger area on PCB) as well as increasing manufacturing cost.

Therefore, a need exists for an enhanced method and apparatus for protecting solder joints from corrosion caused by moisture and carbon dioxide within the chip cavity of a chip module without increasing the use of PCB real estate and increasing manufacturing cost.

### BRIEF DESCRIPTION OF THE INVENTION

The shortcomings of the prior art are overcome and additional advantages are realized through the provision of a multi-chip module with solder corrosion prevention including one or more chips connected to a substrate by soldering, the substrate disposed on a printed circuit board. Additionally, the multi-chip module comprises a molecular sieve desiccant chamber, the molecular sieve desiccant chamber including a quantity of molecular sieve desiccant and also a first cover to contain the one or more chips, the substrate, the first cover having a seal to the printed circuit board. The molecular sieve desiccant chamber is connected to the first cover via a first fluid pathway and a second fluid pathway.

Additionally a method of preventing corrosion of multi-chip module solder connections is provided, including sealing the multi-chip module in a first chamber, connecting the first chamber to a second chamber containing a molecular sieve desiccant with a first fluid pathway and a second fluid pathway. Movement of a fluid in a serial motion is urged from the first chamber through the first fluid pathway to the second chamber and through the second fluid pathway back to the first chamber. Moisture in the fluid is adsorbed by the molecular sieve desiccant in the second chamber.

### BRIEF DESCRIPTION OF THE DRAWINGS

The following descriptions should not be considered limiting in any way. With reference to the accompanying drawings, like elements are numbered alike:

FIG. 1 is a cross sectional view of one embodiment of a multi-chip module with corrosion prevention features;

FIG. 2 is an enlarged view of the circled area “A” of FIG. 1;

FIG. 3 is a cross sectional view of another embodiment of a multi-chip module with corrosion prevention features.

### DETAILED DESCRIPTION OF THE INVENTION

A detailed description of embodiments of the disclosed apparatus and method are presented herein by way of exemplification and not limitation with reference to the Figures.

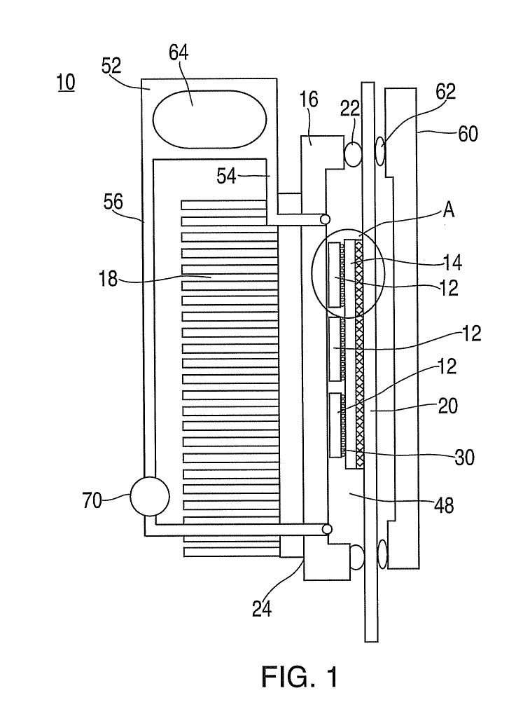

An embodiment of a multi-chip module (MCM) 10 that achieves improved solder joint corrosion resistance is shown in FIG. 1. The MCM 10 includes one or more chips 12 electrically connected to a module substrate 14 via controlled collapse chip connection (C4) solder joints 30. Unlike conventional MCM's, embodiments of MCM 10 do not utilize a polymeric chip underfill to protect the C4 solder joints 30 from corrosion. Omitting this element is advantageous because the chips 12 and the module substrate 14 will then be reworkable, thus reducing manufacturing costs.

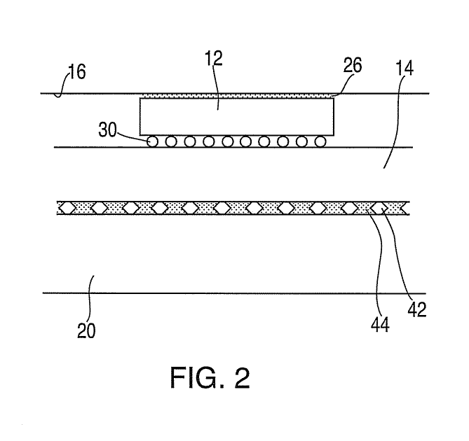

The module substrate 14, in turn, is electrically connected to a printed circuit board (PCB) 20. Various configurations well known in the art are used to electrically connect a set of contacts on the PCB 20 and a set of contacts on the module substrate 14. These configurations include land grid array (LGA), ball grid array (BGA), column grid array (CGA), pin grid array (PGA), and the like. In the embodiment shown in FIG. 2, an LGA 40 electrically connects PCB 20 to the module substrate 14. LGA 40 may comprise, for example, conductive elements 42, such as fuzz buttons which are conductive pads disposed on the module substrate 14 to touch pins on the PCB 20, retained in a non-conductive filler, or interposer 44. One skilled in the art will appreciate, however, that any of the various other configurations may be used in lieu of, or in addition to, an LGA configuration.

The embodiment of an MCM 10 shown in FIG. 1 also includes a cap 16. A heat sink 18 is attached to a top surface of the cap 16, with a first thermally conductive adhesive layer 24 between the heat sink 18 and the top surface of the cap 16. As shown in FIG. 2, the cap 16 is also attached to the one or more chips 12 with a second thermally conductive adhesive layer 26 between a bottom surface of the cap 16 and a top surface of each of the one or more chips 12. Heat sink 18 is also attached to MCM 10 through a conventional LGA mounting mechanism (not shown). In this regard, heat sink 18 includes a plurality of attachment mechanisms (not shown) that project from the bottom surface of heat sink 18. Typically, the attachment mechanisms are positioned around the footprint of module cavity 48. The attachment mechanisms pass through correspondingly positioned through-holes (not shown) in cap 16 and PCB 20. As is well known in the art, the attachment mechanisms cooperate with one or more compression springs (not shown) to urge MCM 10 together with force sufficient to make the electrical connections of LGA 40. Alternatively, those skilled in the art will recognize that other attachment mechanisms may be used. Generally, heat sinks, PCBs and the like, are attached to modules using a variety of attachment mechanisms, such as adhesives, clips, clamps, screws, bolts, barbed push-pins, load posts, and the like.

Heat sink 18 and cap 16 cooperate with various elements to seal the one or more chips 12 and the module substrate 14 within the MCM cavity 48. For example, along the periphery of the bottom end of cap 16, a cap gasket 22, which in one embodiment is formed of butyl rubber, is seated on the cap 16 and urged against the top surface of PCB 20 by the conventional LGA mounting mechanism.

To further enhance sealing of the MCM cavity 48, a stiffener 60 is disposed on a face of the PCB 20 directly opposite to, and with a periphery matching that of the cap 16.The stiffener 60 is attached to the PCB 20 through a conventional LGA mounting mechanism as described above. A stiffener seal 62, which in one embodiment is formed of butyl rubber, is seated on the stiffener 60 and is urged against the bottom surface of the PCB 20 by the conventional LGA mechanism and forms a seal between the stiffener 60 and PCB 20. A component of the LGA mechanism is an array of plated through holes (PTH's) (not shown) in the PCB 20. The seal formed between the stiffener 60 and the PCB 20 by urging the stiffener seal 62 against the PCB 20 minimizes leakage of H₂O and CO₂ into the MCM cavity 48 through the array of PTH's.

The MCM 10 also includes a desiccant chamber 52. One or more permeable molecular sieve desiccant (MSD) containers 64 are disposed within the desiccant chamber 52. Preferably, the one ore more MSD containers 64 contain a total of approximately 156 grams of MSD. Additionally, a first fluid pathway 54 and a second fluid pathway 56 connect the desiccant chamber 52 to the MCM cavity 48.

In the embodiment shown in FIG. 1, a fluid pump 70 is disposed in the second fluid pathway 56. The fluid pump 70 causes air containing moisture and CO₂ to flow from the MCM cavity 48 through the first fluid pathway 54 and into the desiccant chamber 52. The moisture and CO₂ are adsorbed by the MSD in the MSD containers 64. Air having the moisture and CO₂ removed then flows through the second fluid pathway 56 and returns to the MCM cavity 48. Circulation in this manner may be maintained continuously to prevent moisture and CO₂ levels in the MCM cavity 48 from reaching a level that will cause corrosion of the C4 solder joints 30.

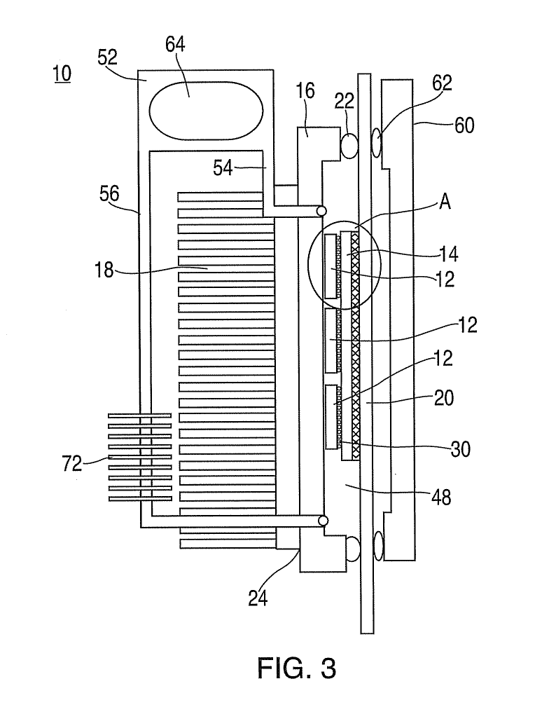

In another embodiment shown in FIG. 3, a heat exchanger 72 is disposed in the second fluid pathway 56. The heat exchanger 72 is employed to create a convective current to circulate air. Air heated in the MCM cavity 48 and containing moisture and CO₂ rises out of the MCM cavity 48 and through the first fluid pathway 54 and into the desiccant chamber 52. The moisture and CO₂ are adsorbed by the MSD in the MSD containers 64. Air having the moisture and CO₂ removed then proceeds into the second fluid pathway 56, where it is cooled by the heat exchanger 72. Once cooled, the air then descends through the second fluid pathway 56 and returns to the MCM cavity 48. The convective current can be maintained continuously to prevent moisture and CO₂ levels in the MCM cavity 48 from reaching a level that will cause corrosion of the C4 solder joints 30.

While the invention has been described with reference to an exemplary embodiment or embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the claims.

What is claimed is:

1. A multi-chip module with solder corrosion prevention comprising:
one or more chips connected to a substrate by soldering, the substrate disposed on a printed circuit board;
a molecular sieve desiccant chamber, the molecular sieve desiccant chamber including a quantity of molecular sieve desiccant;
a first cover to contain the one or more chips and the substrate, the first cover having a seal to the printed circuit board;
a first fluid pathway extending from the first cover to the molecular sieve desiccant chamber; and
a second fluid pathway extending from the molecular sieve desiccant chamber to the first cover.

2. The multi-chip module of claim 1 further comprising a fluid pump disposed in the second port.

3. The multi-chip module of claim 1 further comprising a heat exchanger disposed in the second port.

4. The multi-chip module of claim 1 further comprising a second cover sealing a second side of the printed circuit board opposite a first side of the printed circuit board on which the substrate is disposed.

5. The multi-chip module of claim 1 wherein the first cover includes a seal for sealing to the printed circuit board.

6. The multi-chip module of claim 5 wherein the seal for sealing to the printed circuit board is formed of butyl rubber.

7. The multi-chip module of claim 1 wherein the multi-chip module connects to the printed circuit board by a land grid array.

8. The multi-chip module of claim 1 wherein the soldering is a controlled collapse chip connection.

9. A method of preventing corrosion of multi-chip-module solder connections, comprising:
sealing the multi-chip-module in a first chamber;
connecting the first chamber to a second chamber containing a molecular sieve desiccant with a first fluid pathway port and a second fluid pathway;
urging movement of a fluid in a serial motion from the first chamber through the first port to the second chamber and through the second port back to the first chamber; and
adsorbing moisture from the fluid with the molecular sieve desiccant in the second chamber.

10. The method of claim 9 further comprising adsorbing carbon dioxide from the fluid with the molecular sieve desiccant in the second chamber.

11. The method of claim 9, further comprising:
positioning a first port connection to the first chamber above a second port connection to the first chamber; and
cooling the fluid in the second port, thereby urging the serial motion of the fluid by convection.

12. The method of claim 9, further comprising urging the fluid with a fluid pump.

13. The method of claim 11 further comprising cooling the fluid in the second port with a heat exchanger.
